(19) United States
(12) Patent Application Publication
(10) Pub. No.: US 2026/0255811 A1
(43) Pub. Date: Aug. 27, 2026

(54) DISPLAY PANEL

(71) Applicant: LG Display Co., Ltd., Seoul (KR)

(72) Inventors: Jung June KIM, Paju-si (KR); Seung Hee NAM, Paju-si (KR); Seok Woo SON, Paju-si (KR); Ha Rin KIM, Paju-si (KR)

(21) Appl. No.: 19/421,939

(22) Filed: Dec. 16, 2025

(30) Foreign Application Priority Data
Feb. 26, 2025 (KR) 10-2025-0025104

(51) Int. Cl. H10K 59/124; H10K 59/122; G09G 3/3233

(52) U.S. Cl. CPC H10K 59/124; H10K 59/122; G09G 3/3233; G09G 2300/0426; G09G 2300/0842

(57) ABSTRACT

A display panel includes a substrate including first and second subpixels, a trench insulation layer including a trench structure between the first and second subpixels, a first electrode disposed on the trench insulation layer and provided in the first and second subpixels, a bank covering an edge of the first electrode and exposing a portion of the first electrode, and an emission layer and a second electrode sequentially stacked on the exposed portion of the first electrode, on the bank, and in the trench structure and provided in the first and second subpixels, in which the trench insulation layer includes a first middle electrode therein, a portion of the first middle electrode protruding to an outer portion of the trench insulation layer, and portions of the emission layer in the trench structure are isolated from each other by the protruding portion of the first middle electrode.

### CROSS REFERENCE TO RELATED APPLICATION

This application claims priority from and the benefit of Korean Patent Application No. 10-2025-0025104, filed on February 26, 2025, which is hereby incorporated by reference for all purposes as if fully set forth herein.

### BACKGROUND

### Field

Embodiments of the invention relate generally to a display panel.

### Discussion of the Background

In televisions (TVs), monitors, smartphones, tablet personal computers (PCs), and notebook computers, display apparatuses displaying an image may be used in various modes and types.

Display apparatuses may include a display panel, which includes a plurality of light emitting devices or a liquid crystal for implementing an image and a transistor for controlling an operation of each of the light emitting devices or an operation of the liquid crystal, and may display an image which is to be displayed through the plurality of light emitting devices or the liquid crystal.

Display apparatuses may include a plurality of subpixels each including a light emitting device, and moreover, may include a plurality of driving and switching elements for driving and controlling the light emitting device included in each of the subpixels. Each of the driving and switching elements may be configured as a transistor.

An interval between subpixels may be very small, and a portion of a light emitting device extends to an adjacent subpixel. When such structural characteristics are commonly applied to a plurality of subpixels, attempting to emit light from an arbitrary subpixel may result in a lateral leakage current (LLC) through a portion of a light emitting device, thereby causing unintended light emission from neighboring subpixels. Recently, various research and developments for reducing the LLC are being performed.

The above information disclosed in this Background section is only for understanding of the background of the inventive concepts, and, therefore, it may contain information that does not constitute prior art.

### SUMMARY

Display panels according to an embodiment of the invention are capable of decreasing a lateral leakage current (LLC) occurring between a plurality of subpixels.

Additional features of the inventive concepts will be set forth in the description which follows, and in part will be apparent from the description, or may be learned by practice of the inventive concepts.

A display panel according to an embodiment includes a substrate including a first subpixel and a second subpixel in an upper portion thereof, a trench insulation layer disposed on the substrate and including a trench structure between the first subpixel and the second subpixel, a first electrode disposed on the trench insulation layer and provided in each of the first and second subpixels, a bank disposed on the trench insulation layer to cover an edge of the first electrode and expose a portion of the first electrode, and an emission layer and a second electrode sequentially stacked on the exposed portion of the first electrode, on the bank, and in the trench structure and provided in each of the first and second subpixels, wherein the trench insulation layer includes a first middle electrode therein, a portion of the first middle electrode protrudes to an outer portion of a side surface of the trench insulation layer configuring the trench structure, and a first portion of the emission layer extending from the first subpixel and a second portion of the emission layer extending from the second subpixel are isolated from each other by the protruding portion of the first middle electrode, in the trench structure.

A length of the protruding portion of the first middle electrode may be greater than a thickness of the emission layer or a thickness of the second electrode, and may be less than a thickness of the trench insulation layer.

The trench insulation layer may include a first planarization layer disposed on the substrate and a second planarization layer disposed on the first planarization layer.

The first middle electrode may be disposed between the first planarization layer and the second planarization layer.

Each of the first and second subpixels may further include a transistor between the first planarization layer and the substrate, a second middle electrode disposed between the first planarization layer and the second planarization layer while being horizontally spaced apart from the first middle electrode, and the second middle electrode may electrically connect the first electrode to one of a source electrode and a drain electrode of the transistor.

A portion of the first middle electrode may protrude to an outer portion of a side surface of each of the first and second planarization layers exposed at an inner portion of the trench structure.

A length by which a portion of the first middle electrode protrudes from an outer portion of a side surface of the first planarization layer may be greater than a thickness of the emission layer or a thickness of the second electrode and may be less than a thickness of the first planarization layer or the second planarization layer.

The emission layer and the second electrode may be stacked on a side surface of the second planarization layer exposed at an inner portion of the trench structure, the protruding portion of the first middle electrode, and a bottom surface of the trench structure, in the trench structure.

The emission layer and the second electrode stacked on the protruding portion of the first middle electrode may be respectively spaced apart from the emission layer and the second electrode stacked under the protruding portion of the first middle electrode, in the trench structure.

The bank may be spaced apart from an adjacent bank between the first and second subpixels to expose the trench structure.

The display panel may further include an interlayer insulation layer exposed at a bottom surface of the trench structure, wherein the emission layer and the second electrode may be stacked on the interlayer insulation layer exposed at the bottom surface of the trench structure.

The display panel may further include a capping layer or an encapsulation layer disposed on the second electrode and filling the trench structure.

The first and second subpixels may be included in one unit pixel and emit lights of different colors.

The trench structure may extend in a direction intersecting with a direction in which the first and second subpixels are arranged.

The trench structure may include first and second trench structures in one unit pixel, the first trench structure may be disposed between two subpixels arranged in a first direction and extends in a second direction intersecting with the first direction, the second trench structure may be disposed between two other subpixels arranged in the first direction and extends in the second direction, and the first and second trench structures may be spaced apart from each other between the two subpixels and the two other subpixels, in one unit pixel.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a diagram of a display apparatus according to an embodiment of the invention.

FIG. 2 is a diagram of an equivalent circuit of a subpixel according to an embodiment of the invention.

FIG. 3 is a cross-sectional view of a trench structure according to an embodiment of the invention.

FIG. 4 is an enlarged view of a region K of the embodiment of FIG. 3.

FIG. 5 is a plan view a plane pattern of a trench structure and a plurality of subpixels when a trench structure according to an embodiment of the invention is applied to a display panel.

FIG. 6 is a cross-sectional view of a cross-sectional structure taken along line A-A' of FIG. 5.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

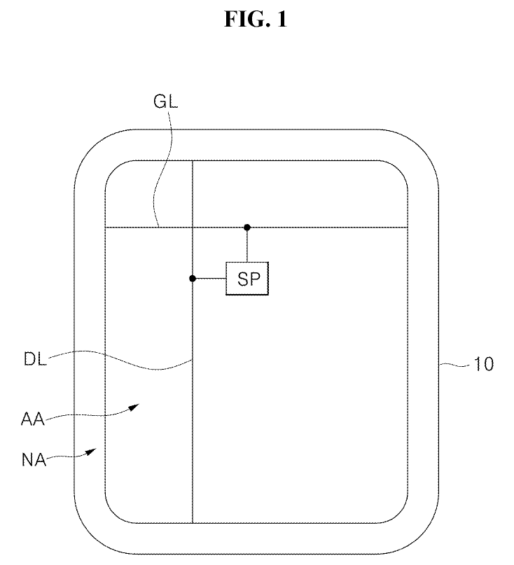

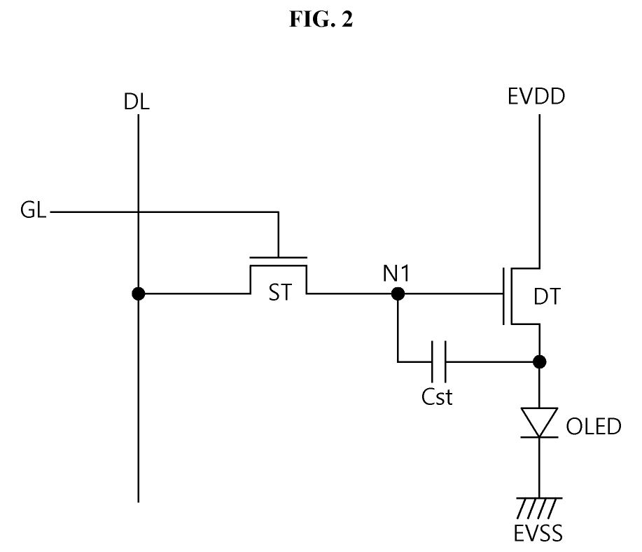

FIG. 1 is a diagram of a display apparatus according to an embodiment of the invention. FIG. 2 is a diagram of an equivalent circuit of a subpixel according to an embodiment of the invention.

Referring to FIG. 1 and FIG. 2, a display apparatus according to an embodiment of the invention may include a display panel 10, and the display panel 10 may include an active area AA and a non-active area NA.

The active area AA may be an area which displays an image. A plurality of subpixels SP may be disposed in the active area AA of the display panel 10, and the active area AA may display an image by using the plurality of subpixels SP. An area where the plurality of subpixels SP are disposed may be the active area AA, and an area other than the active area AA may be the non-active area NA.

The non-active area NA may be an area adjacent to the active area AA. Further, the non-active area NA may be an area disposed adjacent to the active area AA and configured to surround the active area AA. The non-active area NA may be disposed in an edge region surrounding the active area AA which displays an image. However, the present disclosure is not limited thereto.

For example, the non-active area NA may include a first non-display area located outside the active area AA in a first direction, a second non-display area located outside the active area AA in a second direction intersecting the first direction, a third non-display area located outside the active area AA in the opposite direction to the first direction, and a fourth non-display area located outside the active area AA in the direction opposite to the second direction.

For another example, a boundary area between the active area AA and the non-active area NA may be bent so that the non-active area NA may be located below the display area. In this case, when the user looks at the display apparatus from the front, there may be little or no non-active area NA visible to the user.

At least one driver for driving the plurality of subpixels SP may be disposed in the non-active area NA. For example, a scan driver which sequentially supplies a scan signal to a plurality of gate lines may be provided as a gate in panel (GIP) type in the non-active area NA. Furthermore, various additional elements for driving the subpixels SP of the active area AA may be further disposed in the non-active area NA.

At least one subpixel SP among a plurality of subpixels SP, for example, as illustrated in FIG. 2, may include a circuit which includes a switching transistor ST, a driving transistor DT, a capacitor Cst, and a light emitting device OLED.

A first electrode (for example, a drain electrode) of the switching transistor ST may be electrically connected to a data line DL, a second electrode (for example, a source electrode) thereof may be electrically connected to a first node N1, and a gate electrode of the switching transistor ST may be electrically connected to a gate line GL. The switching transistor ST may transfer a data signal, supplied through the data line DL, to the first node N1 in response to a scan signal supplied through the gate line GL.

One end of the capacitor Cst may be electrically connected to the first node N1, the other end thereof may be connected between the driving transistor DT and the light emitting device OLED, and the capacitor Cst may be charged with a voltage applied to the first node N1.

A first electrode (for example, a drain electrode) of the driving transistor DT may be supplied with a high-level driving voltage EVDD, and a second electrode (for example, a source electrode) thereof may be electrically connected to a first electrode (for example, an anode electrode) of the light emitting device OLED. The driving transistor DT may generate a driving current flowing in the light emitting device OLED, based on a voltage applied to a gate electrode thereof.

An active layer of the switching transistor ST and/or the driving transistor DT may include an oxide semiconductor such as indium-gallium-zinc-oxide (IGZO), but is not limited thereto.

The light emitting device OLED may emit light corresponding to the driving current. The light emitting device OLED may emit light corresponding to one color among red (R), green (G), blue (B), and white (W).

The light emitting device OLED may include the anode electrode, an emission layer disposed on the anode electrode, and a cathode electrode supplying a common voltage.

The driving current generated by the driving transistor DT may be applied to the anode electrode of the light emitting device OLED, and the cathode electrode of the light emitting device OLED may be supplied with a low-level driving voltage EVSS.

The emission layer may be implemented to emit light of the same color for each pixel, like white light, or may be implemented to emit light of different colors for each subpixel SP, like red (R) light, green (G) light, or blue (B) light. The light emitting device OLED may be a diode of a top emission type, or may be a diode of a bottom emission type.

In FIG. 2, a case where the driving transistor DT is directly connected to the light emitting device OLED is illustrated as an example, but embodiments of the invention are not limited thereto, and the driving transistor DT may be electrically connected to the light emitting device OLED through another switching transistor ST.

Moreover, although not shown in FIG. 2, a compensation circuit (not shown) for compensating for a threshold voltage Vth of the driving transistor DT may be further included in the subpixel SP. The compensation circuit may include at least one transistor connected to the driving transistor DT and may be provided in the subpixel SP.

Active layers of transistors may be formed of a semiconductor material, such as an oxide semiconductor, amorphous semiconductor, or polycrystalline semiconductor, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

Based on a configuration type, the compensation circuit may have a 3T1C structure where three transistors and one capacitor Cst are included in the subpixel SP, or a 4T2C structure where four transistors and two capacitors Cst are included in the subpixel SP, or various structures such as 5T2C, 6T1C, 6T2C, 7T1C, and 7T2C.

In conventional display panels, an interval between a plurality of subpixels may be very small, and an emission layer includes a common layer which extends from one subpixel to an adjacent subpixel. Due to this, when desiring to emit light from an arbitrary subpixel, a lateral leakage current (LLC) may occur through the common layer of the emission layer, and an undesired subpixel may emit light together.

On the other hand, in the display panel according to an embodiment of the invention, a trench insulation layer having a trench structure may be provided between two adjacent subpixels, a portion of a first middle electrode included in the trench insulation layer may have a structure which protrudes to an outer portion of a side surface of the trench insulation layer, and an emission layer which is provided in common between two adjacent subpixels may be divided by a portion of the first middle electrode, and thus, a lateral leakage current (LLC) may be reduced.

Hereinafter, a structure of a display panel for reducing an LLC will be described in detail.

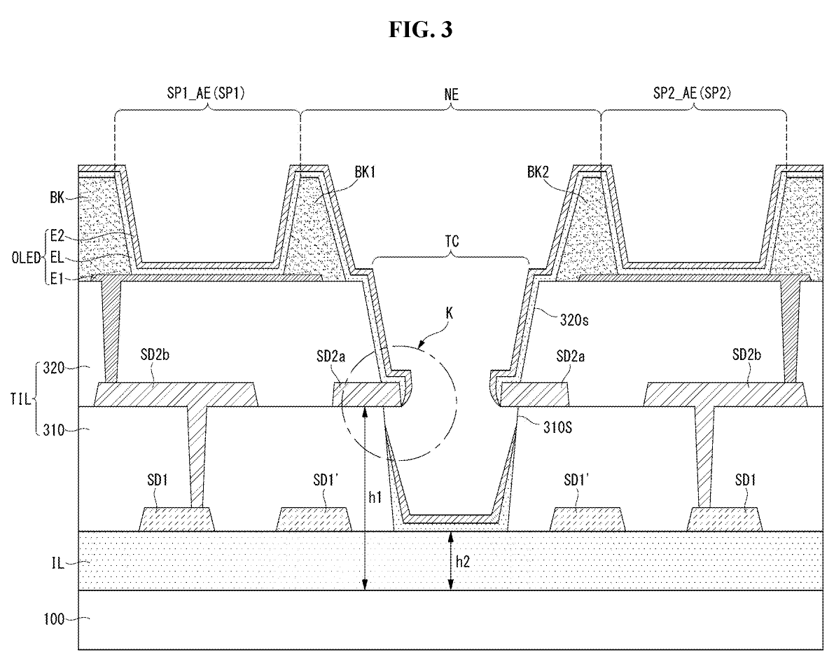

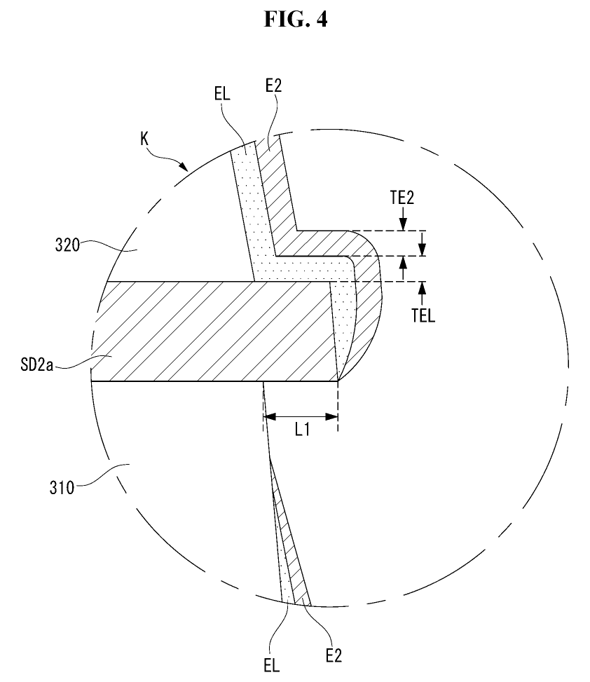

FIG. 3 is a cross-sectional view of a trench structure according to an embodiment of the invention. FIG. 4 is an enlarged view of a region K of FIG. 3.

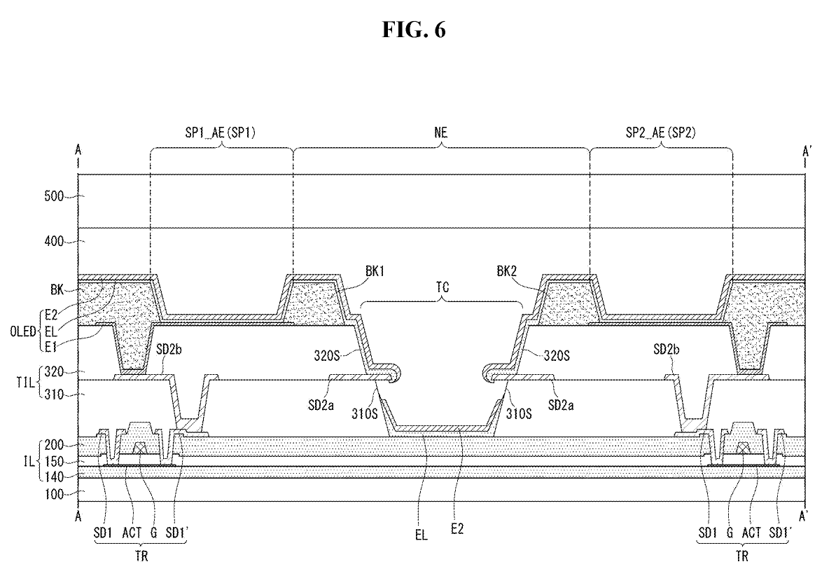

In FIG. 3, in order to describe the concept of a trench structure TC, various detailed elements (for example, a transistor, an encapsulation layer, etc.) configuring a display panel are omitted. Detailed elements of a display panel will be described below with reference to FIG. 6.

In describing FIG. 3, descriptions of detailed materials of a substrate 100, an insulation layer IL, and a trench insulation layer TIL are omitted, a structure may be mainly described, and the detailed materials of the substrate 100, the insulation layer IL, and the trench insulation layer TIL will be described below in detail with reference to FIG. 6.

As illustrated in FIG. 3, a display panel having a trench structure TC according to an embodiment of the invention may include the substrate 100, the insulation layer IL, the trench insulation layer TIL, a first electrode E1, a bank BK, an emission layer EL, and a second electrode E2.

The substrate 100 may support a plurality of subpixels in the display panel, and for example, as in FIG. 3, a first subpixel SP1 and a second subpixel SP2 may be provided at an upper portion. The first and second subpixels SP1 and SP2 may emit lights of different colors. For example, in a case where the first subpixel SP1 emits red (R) light, the second subpixel SP2 may emit green (G) light, or in a case where the first subpixel SP1 emits green (G) light, the second subpixel SP2 may emit blue (B) light. However, the present disclosure is not limited thereto, for example, in a case where the first subpixel SP1 emits blue (B) light, the second subpixel SP2 may emit red (R) light.

The insulation layer IL may be disposed on the substrate 100, and transistors for driving the first and second subpixels SP1 and SP2 may be disposed in the insulation layer IL. For example, transistors such as the switching transistor ST and the driving transistor DT described with reference to FIG. 2 may be provided in the insulation layer IL.

A source electrode SD1 and a drain electrode SD1' connected to the switching transistor ST or the driving transistor DT may be disposed on the insulation layer IL.

The trench insulation layer TIL may be disposed on the insulation layer IL, and a function of planarizing an upper surface may be performed by removing a step height caused by the switching transistor ST or the driving transistor DT. The trench insulation layer TIL may include first and second middle electrodes SD2a and SD2b which are isolated from each other and are electrically insulated from each other.

A portion of the first middle electrode SD2a may protrude to an outer portion of each of side surfaces 310S and 320S of the trench insulation layer TIL configuring the trench structure TC. In the trench structure TC, an emission layer EL extending from the first subpixel SP1 and an emission layer EL extending from the second subpixel SP2 may be spaced apart from and isolated from each other by the protruding portion of the first middle electrode SD2a.

The second middle electrode SD2b may be disposed on the same layer as a layer where the first middle electrode SD2a is disposed, in the trench insulation layer TIL, and may be disposed apart from the first middle electrode SD2a in a horizontal direction. For example, the trench insulation layer TIL may include a first planarization layer 310 and a second planarization layer 320. The first planarization layer 310 may be disposed on the insulation layer IL, and the second planarization layer 320 may be disposed on the first planarization layer 310. The first and second middle electrodes SD2a and SD2b may be disposed between the first and second planarization layers 310 and 320 and may be spaced apart from each other in the horizontal direction. Accordingly, the first and second middle electrodes SD2a and SD2b may be insulated from each other.

The second middle electrode SD2b may electrically connect the first electrode E1 to one of the source electrode SD1 and the drain electrode SD1' of the transistor. For example, the second middle electrode SD2b may pass through the first planarization layer 310 and may be electrically connected to one electrode, and the first electrode E1 may pass through the second planarization layer 320 and may be electrically connected to the second middle electrode SD2b.

The trench insulation layer TIL may include the trench structure TC between the first and second subpixels SP1 and SP2. In FIG. 3, an emission region SP1_AE of a first subpixel may be included in the first subpixel SP1, and an emission region SP2_AE of a second subpixel may be included in the second subpixel SP2. The other elements illustrated in FIG. 3 may be described, and then, the trench structure TC of the trench insulation layer TIL may be described.

A light emitting device OLED may include a first electrode E1, an emission layer EL, and a second electrode E2. In the first and second subpixels SP1 and SP2, the emission layer EL and the second electrode E2 may be sequentially stacked on the first electrode E1.

The first electrode E1 may be disposed on the trench insulation layer TIL, may function as an anode electrode of the light emitting device OLED, and may be provided apart from the other elements in each of the first and second subpixels SP1 and SP2.

In a case where the display panel 10 has a structure of a top emission type where light is emitted toward a top of the substrate 100 as in FIG. 3, the first electrode E1 may include a conductive material and may include a structure where a transparent conductive layer (not shown) and a reflective layer (not shown) under the transparent conductive layer are stacked. The transparent conductive layer may include transparent conductive oxide such as indium tin oxide (ITO) or indium zinc oxide (IZO), and the reflective layer may include, for example, silver (Ag), aluminum (Al), gold (Au), molybdenum (Mo), and tungsten (W), chrome (Cr), or an alloy thereof.

Therefore, the first electrode E1 may reflect light incident from a front surface where the emission layer EL is disposed, based on a high reflectance of the reflective layer.

The emission layer EL may generate light of luminance corresponding to a voltage difference between the first electrode E1 and the second electrode E2. For example, the emission layer EL may include an emission material layer (EML) including an emission material. The emission material may include an organic material, an inorganic material, or a hybrid material. For example, the emission layer EL may include an emission material layer including an organic material. but the present disclosure is not limited thereto, for example, the emission layer EL may include an emission material layer including both an organic material and an inorganic material.

The second electrode E2 may include a conductive material. The second electrode E2 may include a material which differs from that of the first electrode E1. For example, the second electrode E2 may be a transparent electrode including a transparent conductive material such as ITO or IZO. The second electrode E2 may have a transmittance which is higher than that of the first electrode E1.

For example, the second electrode E2 may include transparent metal oxide such as ITO or IZO, but is not limited thereto. When a display apparatus has a top emission type, the second electrode E2 may be disposed by using a semitransparent conductive material which transmits light. For example, the second electrode E2 may include one or more of alloys such as LiF/Al, CsF/Al, Mg:Ag, Ca/Ag, Ca:Ag, LiF/Mg:Ag, LiF/Ca/Ag, and LiF/Ca:Ag.

The bank BK may be disposed on the trench insulation layer TIL, may cover an edge of the first electrode E1, and may expose a center portion of the first electrode E1. The emission layer EL and the second electrode E2 may be disposed on a partial region of the first electrode E1 exposed by the bank BK.

The bank BK may define an emission region AE of each subpixel. That is, the emission region AE of each subpixel may be divided by the bank BK. In detail, each of the emission region SP1_AE of the first subpixel SP1 and the emission region SP2_AE of the second subpixel SP2 may be a region between adjacent banks BK, and a non-emission region NE may be disposed between the first and second subpixels SP1 and SP2 and may be the other region except the emission region SP1_AE of the first subpixel SP1 and the emission region SP2_AE of the second subpixel SP2.

The bank BK may be spaced apart from each other between the first and second subpixels SP1 and SP2 and may expose the trench structure TC. For example, the first bank BK1 defining the emission region AE of the first subpixel SP1 and the second bank BK2 defining the emission region AE of the second subpixel SP2 may be spaced apart from each other with respect to the trench structure TC disposed in the non-emission region NE between the first and second subpixels SP1 and SP2, and the trench structure TC may be exposed between the first and second banks BK1 and BK2.

The emission layer EL and the second electrode E2 may be stacked on an upper surface of the first electrode E1 exposed by the bank BK and an upper surface of the bank BK and in the trench structure TC. Here, the emission layer EL and the second electrode E2 may be spaced apart from and isolated from each other by a portion of the first middle electrode SD2a protruding to an outer portion of each of the side surfaces 310S and 320S of the trench insulation layer TIL, in the trench structure TC. For example, each of the emission layer EL and the second electrode E2 may be spaced apart from and isolated from each other by a portion of the first middle electrode SD2a protruding to an outer portion of each of the side surfaces 310S and 320S of the trench insulation layer TIL, in the trench structure TC. For example, on a lower surface of a portion of the first middle electrode SD2a protruding to an outer portion of each of the side surfaces 310S and 320S of the trench insulation layer TIL, the emission layer EL and the second electrode E2 may be not provided. However, the present disclosure is not limited thereto.

Moreover, the first middle electrode SD2a may be disposed between the first planarization layer 310 and the second planarization layer 320 and may solidly fix ends of the first planarization layer 310 and the second planarization layer 320. Also, the first middle electrode SD2a may be disposed to protrude between the first planarization layer 310 and the second planarization layer 320, and thus, a path through which water penetrates into a gap between the first planarization layer 310 and the second planarization layer 320 may be long formed, thereby reinforcing reliability against water penetration.

The trench structure TC of the trench insulation layer TIL may be disposed between the first and second subpixels SP1 and SP2 and may have a structure where the trench insulation layer TIL is recessed to be deeper than a height level of the first middle electrode SD2a. For example, a first distance h1 up to the first middle electrode SD2a from the substrate 100 may be greater than a second distance h2 up to a bottom surface of the trench structure TC from the substrate 100.

For example, as in FIG. 3, an upper surface of the insulation layer IL may be exposed at the bottom surface of the trench structure TC. However, this may be an example, and embodiments of the invention are not limited thereto. For example, unlike FIG. 3, the insulation layer IL may not be exposed at the bottom surface of the trench structure TC, and a portion of the first planarization layer 310 may configure a portion of the trench structure TC.

A portion of the first middle electrode SD2amay protrude to the outer portion of each of the side surfaces 310S and 320S of the trench insulation layer TIL configuring the trench structure TC. For example, a portion of the first middle electrode SD2a may protrude to outer portions of side surfaces 310S and 320S of the first and second planarization layers 310 and 320 exposed at the inside of the trench structure TC.

In the trench structure TC, the emission layer EL and the second electrode E2 may be stacked on the side surface 320S of the second planarization layer 320 exposed at the inside of the trench structure TC, a protruding portion of the first middle electrode SD2a, and the bottom surface of the trench structure TC. For example, in the trench structure TC, the emission layer EL and the second electrode E2 may be stacked on the side surface 320S of the second planarization layer 320 exposed at the inside of the trench structure TC, a protruding portion of the first middle electrode SD2a, a portion of the side surface 310S of the first planarization layer 310 exposed at the inside of the trench structure TC and the bottom surface of the trench structure TC.

A portion of the first middle electrode SD2a may protrude to the outer portions of the side surfaces 310S and 320S of the first and second planarization layers 310 and 320, and thus, the emission layer EL extending from the first subpixel SP1 and the emission layer EL extending from the second subpixel SP2 may be spaced apart from and isolated from each other in the trench structure TC.

In detail, an emission layer EL and a second electrode E2 stacked on the first middle electrode SD2a protruding from the trench structure TC may be spaced apart from an emission layer EL and a second electrode E2 stacked on a lower portion (i.e., a bottom surface) of the protruding first middle electrode SD2a. Accordingly, the emission layer EL extending from the first subpixel SP1 may be spaced apart from the emission layer EL extending from the second subpixel SP2.

Therefore, an LLC flowing from the emission layer EL of the first subpixel SP1 to the emission layer EL of the second subpixel SP2 may be prevented. Accordingly, embodiments of the invention may enhance the image quality of a display panel.

As illustrated in FIG. 4, a length L1 by which a portion of the first middle electrode SD2a protrudes may be greater than a sum of a thickness TEL of the emission layer EL and a thickness TE2 of the second electrode E2. For example, the length L1 by which a portion of the first middle electrode SD2a protrudes may be greater than each of the thickness TEL of the emission layer EL or the thickness TE2 of the second electrode E2.

Moreover, the length L1 by which a portion of the first middle electrode SD2a protrudes may be less than a thickness of the trench insulation layer IL. When the trench insulation layer IL includes the first planarization layer 310 and the second planarization layer 320, the length L1 by which a portion of the first middle electrode SD2a protrudes may be less than a sum of thicknesses of the first planarization layer 310 and the second planarization layer 320. For example, the length L1 by which a portion of the first middle electrode SD2a protrudes may be less than each of the thickness of the first planarization layer 310 or the thickness of the second planarization layer 320.

The length L1 by which a portion of the first middle electrode SD2a protrudes may be greater than the thickness TEL of the emission layer EL or the thickness TE2 of the second electrode E2, and thus, the emission layer EL may be sufficiently spaced apart from the second electrode E2, in the trench structure TC.

Moreover, the length L1 by which a portion of the first middle electrode SD2a protrudes may be less than the thickness of the first planarization layer 310 or the thickness of the second planarization layer 320, and thus, the first middle electrode SD2a may not excessively protrude. For example, as in FIG. 4, when the first middle electrode SD2a protrudes from both side surfaces of the trench structure TC, first middle electrodes SD2a protruding to outer portions of both side surfaces 310S and 320S of the first and second planarization layers 310 and 320 may not contact each other. For example, with reference to FIG. 3, the first middle electrodes SD2a protruding to outer portions of both side surfaces 310S and 320S of the first and second planarization layers 310 and 320 in first subpixel SP1 and the first middle electrodes SD2a protruding to outer portions of both side surfaces 310S and 320S of the first and second planarization layers 310 and 320 in second subpixel SP2 may not contact each other and may be spaced apart from each other.

In FIG. 3, it is illustrated that cross-sectional structures of the first and second subpixels SP1 and SP2 are laterally symmetrical with respect to the trench structure TC, but this may be an example and embodiments of the invention are not limited thereto.

Hereinafter, an example where the trench structure TC according to an embodiment described above with reference to FIGS. 3 and 4 is applied to a display panel will be described in more detail.

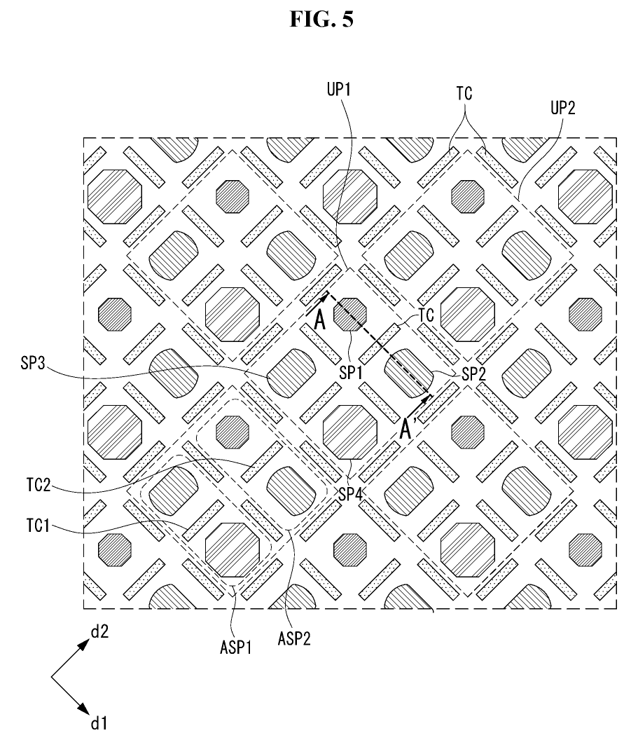

FIG. 5 is a plan view of a plane pattern of a trench structure and a plurality of subpixels when a trench structure according to an embodiment of the invention is applied to a display panel.

In FIG. 5, for convenience of understanding, a plane pattern of a trench structure TC and a plurality of subpixels is illustrated, and the other elements are omitted for convenience of understanding. Each of a plurality of subpixels illustrated in FIG. 5 may denote an emission region AE of each subpixel.

As illustrated in FIG. 5, a plurality of unit pixels may be disposed on a substrate 100 and may be arranged in a first direction d1 and a second direction d2.

Each of the plurality of unit pixels may include first to fourth subpixels SP1 to SP4. For example, in each of the plurality of unit pixels, the first subpixel SP1 may emit red (R) light, the second and third subpixels SP2 and SP3 may emit green (G) light, and the fourth subpixel SP4 may emit blue (B) light. The first and second subpixels SP1 and SP2 may be arranged apart from each other in the first direction d1, the first and third subpixels SP1 and SP3 may be arranged apart from each other in the second direction d2 intersecting with the first direction d1, and the fourth subpixel SP4 may be arranged apart from the third subpixel SP3 in the first direction d1.

The trench structure TC may extend in a direction intersecting with a direction in which a plurality of subpixels are arranged, in each unit pixel.

For example, as in FIG. 5, in a first unit pixel UP1, first and second subpixels SP1 and SP2 may be arranged in a first direction d1, a trench structure TC may be disposed between the first and second subpixels SP1 and SP2, and the trench structure TC disposed between the first and second subpixels SP1 and SP2 may extend in a second direction d2. Furthermore, in the first unit pixel UP1, first and third subpixels SP1 and SP3 may be arranged in the second direction d2, and a trench structure TC disposed between the first and third subpixels SP1 and SP3 may extend in the first direction d1.

Based on such a pattern structure, trench structures TC may be respectively disposed between the first and second subpixels SP1 and SP2, between the first and third subpixels SP1 and SP3, between third and fourth subpixels SP3 and SP4, and between the second and fourth subpixels SP2 and SP4.

Here, each trench structure TC disposed in one unit pixel may be spaced apart from an adjacent trench structure TC.

For example, as in FIG. 5, each trench structure TC may include first and second trench structures TC1 and TC2 included in one unit pixel.

In this case, the first trench structure TC1 may be disposed between two subpixels arranged in the first direction d1 and may extend in the second direction d2 intersecting with the first direction d1, and the second trench structure TC2 may be disposed between two other subpixels arranged in the first direction d1 and may extend in the second direction d2. For example, the first trench structure TC1 may be disposed between third and fourth subpixels SP3 and SP4 arranged in the first direction d1 and may extend in the second direction d2 intersecting with the first direction d1, and the second trench structure TC2 may be disposed between the first and second subpixels SP1 and SP2 arranged in the first direction d1 and may extend in the second direction d2. However, the present disclosure is not limited thereto.

In this case, the first and second trench structures TC1 and TC2 may be spaced apart from each other between two subpixels and two other subpixels, in one unit pixel.

As described above, in one unit pixel, two trench structures TC extending in the first direction d1 may be spaced apart from each other, and two trench structures TC extending in the second direction d2 may be spaced apart from each other.

Moreover, as in FIG. 5, in a case where the first and second unit pixels UP1 and UP2 are arranged in the second direction d2, a trench structure TC extending in the first direction d1 may be disposed between one subpixel (for example, SP1) of the first unit pixel UP1 and another subpixel (for example, SP3) of the second unit pixel UP2.

FIG. 6 is a cross-sectional view for describing a cross-sectional structure taken along line A-A' of FIG. 5.

A display panel to which a trench structure TC according to an embodiment of the invention is applied may be as illustrated in FIG. 6 as an example. An application example of the trench structure TC of FIG. 6 may be an example, and embodiments of the invention are not limited thereto. Hereinafter, the display panel to which the trench structure TC according to an embodiment of the invention is applied will be described with reference to FIG. 6 as an example.

In FIG. 6, a transistor TR may be one of the switching transistor ST and the driving transistor DT illustrated in FIG. 2. As described above with reference to FIG. 3, the transistor TR may be disposed in an insulation layer IL, and a case where the insulation layer IL includes a buffer layer 140, a gate insulation layer 150, and an interlayer insulation layer 200 is illustrated in FIG. 6 as an example.

As illustrated in FIG. 6, a display panel to which a trench structure TC according to an embodiment is applied may include a substrate 100, a buffer layer 140, a gate insulation layer 150, an interlayer insulation layer 200, a transistor TR, a first planarization layer 310, a second planarization layer 320, first and second middle electrodes SD2a and SD2b, a light emitting device OLED, a bank BK, a capping layer 400, and an encapsulation layer 500.

The substrate 100 may include a plastic material having flexibility and may have a flexible characteristic, and moreover, may include a glass material of a thin thickness having flexibility. For example, the substrate 100 may include a flexible polymer film. For example, the flexible polymer film may be made of any one of polyimide (PI), polyethylene terephthalate (PET), acrylonitrile-butadiene-styrene copolymer(ABS), polymethyl methacrylate(PMMA), polyethylene naphthalate (PEN), polycarbonate (PC), polyethersulfone (PES), polyarylate (PAR), polysulfone (PSF), cyclic olefin copolymer(COC), triacetylcellulose(TAC), polyvinyl alcohol(PVA), and polystyrene(PS). For example, the substrate 100 may include a transparent polyimide material, and the present disclosure is not limited thereto. The substrate 100 may be disposed in an active area AA and a non-active area NA of the display panel.

The buffer layer 140 may be provided on the substrate 100. The buffer layer 140 may include at least one inorganic insulating material such as silicon oxide (SiOx), silicon nitride (SiNx), and silicon oxynitride (SiOxNy). The buffer layer 140 may be formed as a single layer made of an inorganic material or a multilayer made of different inorganic materials. For example, the buffer layer 140 may be formed as a single layer of any one of a silicon oxide (SiOx) film, a silicon nitride (SiNx) film, and a silicon oxynitride (SiON) film, or a multilayer thereof. For example, the buffer layer 140 may be formed by inorganic film in a single layer or in multiple layers, for example, the inorganic film in a single layer may be a silicon oxide (SiOx) film, a silicon nitride (SiNx) film or silicon oxynitride (SiON) film, and inorganic films in multiple layers may formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto. The buffer layer 140 may include a multi-layer structure including the same material or different materials. The buffer layer 140 may be disposed on the substrate 100 and may protect structures of the substrate 100 vulnerable to water penetration against water penetrating through the substrate 100.

The transistor TR may be disposed on the buffer layer 140. The transistor TR may be disposed in a region corresponding to each of the first and second subpixels SP1 and SP2, on the buffer layer 140.

The transistor TR included in each of the first and second subpixels SP1 and SP2 may include a gate electrode G, a source electrode SD1, a drain electrode SD1', and an active layer ACT.

The active layer ACT may be disposed on the buffer layer 140 and may include an oxide semiconductor such as indium gallium zinc oxide (IGZO) or may include a low-temperature polycrystalline silicon (LTPS) semiconductor.

Although not shown, the active layer ACT may include a source region, a channel region, and a drain region. The channel region may be disposed in a region, overlapping the gate electrode G, of the active layer ACT, and the source region and the drain region may be disposed outside the channel region, which does not overlap the gate electrode G, of the active layer ACT.

The channel region may have a carrier concentration which is lower than that of the source region and the drain region and may form a channel which allows a carrier to move, in response to a voltage applied to the gate electrode G. The source region and the drain region may have an electrical conductivity and a carrier concentration, which are higher than those of the channel region.

The gate insulation layer 150 may be stacked on the buffer layer 140 to cover the active layer ACT. The gate insulation layer 150 may insulate the gate electrode G and the active layer ACT of the transistor TR from each other. The gate insulation layer 150 may include an inorganic insulating material such as SiOx, SiNx, and SiOxNy. The gate insulation layer 150 may be formed as a single layer made of an inorganic material or a multilayer made of different inorganic materials. For example, the gate insulation layer 150 may be formed as a single layer of any one of a silicon oxide (SiOx) film, a silicon nitride (SiNx) film, and a silicon oxynitride (SiON) film, or a multilayer thereof. For example, the gate insulation layer 150 may be formed by inorganic film in a single layer or in multiple layers, for example, the inorganic film in a single layer may be a silicon oxide (SiOx) film, a silicon nitride (SiNx) film or silicon oxynitride (SiON) film, and inorganic films in multiple layers may formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto.

The interlayer insulation layer 200 may be disposed on the gate insulation layer 150 to cover the gate electrode G. The source electrode SD1 and the drain electrode SD1' of the transistor TR may be disposed on the interlayer insulation layer 200. The interlayer insulation layer 200 may include an inorganic insulating material such as SiOx, SiNx, and SiOxNy. The interlayer insulation layer 200 may be formed as a single layer made of an inorganic material or a multilayer made of different inorganic materials. For example, the interlayer insulation layer 200 may be formed as a single layer of any one of a silicon oxide (SiOx) film, a silicon nitride (SiNx) film, and a silicon oxynitride (SiON) film, or a multilayer thereof. For example, the interlayer insulation layer 200 may be formed by inorganic film in a single layer or in multiple layers, for example, the inorganic film in a single layer may be a silicon oxide (SiOx) film, a silicon nitride (SiNx) film or silicon oxynitride (SiON) film, and inorganic films in multiple layers may formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto.

The source electrode SD1 and the drain electrode SD1' of the transistor TR may pass through the interlayer insulation layer 200 and the gate insulation layer 150 and may contact the source region and the drain region of the active layer ACT.

Here, the buffer layer 140, the gate insulation layer 150, and the interlayer insulation layer 200 may be included in the insulation layer IL described above with reference to FIG. 3.

The first and second planarization layers 310 and 320 may be stacked on the interlayer insulation layer 200 to cover the source electrode SD1 and the drain electrode SD1' of the transistor TR. The first and second planarization layers 310 and 320 may remove a step height caused by a driving circuit, and an upper surface of each of the first and second planarization layers 310 and 320 may include a flat surface. The first and second planarization layers 310 and 320 may include an organic insulating material having high flowability. The first and second planarization layers 310 and 320 may be included in the trench insulation layer TIL described above with reference to FIGS. 3 and 4.

The first planarization layer 310 may be stacked on the interlayer insulation layer 200 to cover the source electrode SD1 and the drain electrode SD1' of the transistor TR, and the first and second middle electrodes SD2a and SD2b may be disposed apart from each other on an upper surface of the first planarization layer 310.

The second planarization layer 320 may be disposed on the first planarization layer 310 to cover the first and second middle electrodes SD2a and SD2b.

The first middle electrode SD2a may be disposed between the first and second subpixels SP1 and SP2 may be disposed to overlap the bank BK. The first middle electrode SD2a, as described above with reference to FIGS. 3 and 4, may protrude to outer portions of the side surfaces 310S and 320S of the trench insulation layer TIL configuring the trench structure TC, which may be disposed in the non-emission region NE, and may isolate the emission layer EL in the trench structure TC to isolate, from each other, the emission layer EL extending from the first subpixel SP1 and the emission layer EL extending from the second subpixel SP2.

The second middle electrode SD2b may electrically connect the first electrode E1 to one of the source electrode SD1 and the drain electrode SD1' of the transistor TR. For example, as in FIG. 6, the second middle electrode SD2b may pass through the first planarization layer 310 and may be connected to one of the source electrode SD1 and the drain electrode SD1' of the transistor TR, and the first electrode E1 may pass through the second planarization layer 320 and may be connected to the second middle electrode SD2b.

In FIG. 6, a case where the second middle electrode SD2b of the first subpixel SP1 is connected to the drain electrode SD1' of the transistor TR and the second middle electrode SD2b of the second subpixel SP2 is connected to the source electrode SD1 of the transistor TR is illustrated as an example, but embodiments of the invention are not limited thereto.

Therefore, one electrode included in the transistor TR may electrically contact the first electrode E1 of the light emitting device OLED.

The bank BK may be disposed on the second electrode E2. The bank BK may include an organic insulating material. The bank BK may cover an edge of the first electrode E1. The emission layer EL and the second electrode E2 may be stacked on a partial region of the first electrode E1 exposed by the bank BK.

The first electrode E1, the emission layer EL, and the second electrode E2 of the light emitting device OLED have been described above with reference to FIG. 3, and thus, their descriptions may be replaced with the descriptions of FIG. 3.

As described above with reference to FIG. 3, the trench structure TC may be provided in the first and second planarization layers 310 and 320, between the first and second subpixels SP1 and SP2, and the bank BK may be spaced apart from an adjacent bank between the first and second subpixels SP1 and SP2 and may expose the trench structure TC. A detailed structure of the trench structure TC may be replaced with the above descriptions of FIGS. 3 and 4.

In a state where the trench structure TC is deposited up to the first and second planarization layers 310 and 320, the first electrode E1, and the bank BK, the trench structure TC may be formed by etching, in a thickness direction, a portion of each of the first and second planarization layers 310 and 320 and the bank BK disposed between subpixels including the first and second subpixels SP1 and SP2 so as to have the plane pattern of the trench structure TC described above with reference to FIG. 5.

In a process of etching a portion of each of the first and second planarization layers 310 and 320 and the bank BK in a thickness direction, the first middle electrode SD2a may have a state where the first middle electrode SD2a is exposed at outer portions of the side surfaces of the first and second planarization layers 310 and 320 configuring the trench structure TC and protrudes.

Moreover, based on a degree of etching, the interlayer insulation layer 200 may be exposed at a bottom surface of the trench structure TC, or a portion of the first planarization layer 310 may be formed as the bottom surface of the trench structure TC.

As described above, after the trench structure TC is formed, the emission layer EL and the second electrode E2 configuring the light emitting device OLED may be sequentially stacked on the first electrode E1 and the bank BK and in the trench structure TC, and thus, a structure illustrated in FIG. 6 may be formed.

As in FIG. 6, when the interlayer insulation layer 200 exposed at the bottom surface of the trench structure TC is exposed, the emission layer EL and the second electrode E2 may be stacked on the interlayer insulation layer 200 exposed at the bottom surface of the trench structure TC.

Here, an emission layer EL and a second electrode E2 deposited on the first middle electrode SD2a may be naturally formed apart from an emission layer EL and a second electrode E2 deposited under the second middle electrode SD2b, based on the first middle electrode SD2a exposed at the outer portions of the side surfaces of the first and second planarization layers 310 and 320 configuring the trench structure TC. In embodiments of the invention, because the first middle electrode SD2a is provided to protrude in the trench structure TC, the emission layer EL extending from the first subpixel SP1 and the emission layer EL extending from the second subpixel SP2 may be naturally spaced apart from each other in a manufacturing process, thereby preventing an LLC.

The capping layer 400 and the encapsulation layer 500 may be sequentially stacked and disposed on the second electrode E2.

The capping layer 400 may be disposed on the second electrode E2 and may include an inorganic insulating material layer, or may include an organic insulating material layer disposed on the second electrode E2 and an inorganic insulating material layer disposed on the organic insulating material layer. The capping layer 400 may be disposed on the second electrode E2 and may prevent the penetration of water from the outside, thereby preventing the second electrode E2 or the emission layer EL from being damaged by water.

The encapsulation layer 500 may be disposed on the capping layer 400 and may prevent the light emitting device OLED from being damaged by an external impact and water. The encapsulation layer 500 may include an inorganic insulating material layer and an inorganic insulating material layer, which are alternately stacked. For example, the organic insulating material layer may be disposed between adjacent inorganic insulating material layers.

For example, the encapsulation layer includes a first inorganic encapsulation layer, a first organic encapsulation layer, and a second inorganic encapsulation layer stacked sequentially.

Alternatively, the encapsulation layer includes a first inorganic encapsulation layer, a first organic encapsulation layer, a second inorganic encapsulation layer, a second organic encapsulation layer, and a third inorganic encapsulation layer stacked sequentially. However, the present disclosure is not limited thereto.

The first inorganic encapsulation layer, the second inorganic encapsulation layer, and the third inorganic encapsulation layer may serve to block the penetration of moisture or oxygen. The first inorganic encapsulation layer, the second inorganic encapsulation layer, and the third inorganic encapsulation layer may be made of an inorganic material, for example, an inorganic material such as silicon nitride (SiNx), silicon oxide (SiOx), or aluminum oxide (AlOx). However, the present disclosure is not limited thereto.

The first organic encapsulation layer is disposed between the first inorganic encapsulation layer and the second inorganic encapsulation layer, and the second organic encapsulation layer is disposed between the second inorganic encapsulation layer and the third inorganic encapsulation layer. The first organic encapsulation layer and the second organic encapsulation layer may each have a larger thickness than each of the first inorganic encapsulation layer, the second inorganic encapsulation layer, and the third inorganic encapsulation layer in order to adsorb or block particles that may be produced during a process of manufacturing the display device. The first organic encapsulation layer and the second organic encapsulation layer may fill cracks that may be formed in the first inorganic encapsulation layer and the second inorganic encapsulation layer. The first organic encapsulation layer and the second organic encapsulation layer may planarize an upper portion of the first inorganic encapsulation layer and an upper portion of the second inorganic encapsulation layer by covering particles on the first inorganic encapsulation layer and the second inorganic encapsulation layer respectively. For example, the first organic encapsulation layer may planarize an upper portion of the first inorganic encapsulation layer by covering particles on the first inorganic encapsulation layer. For example, the second organic encapsulation layer may planarize an upper portion of the second inorganic encapsulation layer by covering particles on the second inorganic encapsulation layer. The first organic encapsulation layer and the second organic encapsulation layer may be made of an organic material, and for example, epoxy polymer, acrylic polymer, or the like may be used. However, the present disclosure is not limited thereto.

Meanwhile, the encapsulation layer is not limited to three or five layers, for example, n layers alternately stacked between inorganic encapsulation layer and organic encapsulation layer (where n is an integer greater than 3) may be included.

In FIG. 6, a case where the capping layer 400 is disposed between the second electrode E2 and the encapsulation layer 500 is illustrated as an example, but embodiments of the invention are not limited thereto and in a state where the capping layer 400 is omitted, the encapsulation layer 500 may be stacked and disposed on the second electrode E2.

As in FIG. 6, in a case where the capping layer 400 is stacked on the second electrode E2, the capping layer 400 may be stacked on the second electrode E2 disposed in the trench structure TC, and the capping layer 400 may be filled in a space formed by the trench structure TC.

As described above, in embodiments of the invention, the trench insulation layer TIL having the trench structure TC may be disposed between the first and second subpixels SP1 and SP2, and a portion of the first middle electrode SD2a included in the trench insulation layer TIL may have a structure which protrudes to an outer portion of each of the side surfaces 310S and 320S of the trench insulation layer TIL, and thus, the emission layer EL and the second electrode E2 of the first subpixel SP1 may be electrically isolated from the emission layer EL and the second electrode E2 of the second subpixel SP2, thereby reducing the LLC.

In embodiments of the invention, a trench insulation layer having a trench structure may be disposed between first and second subpixels, and a portion of a first middle electrode included in the trench insulation layer may have a structure which protrudes to an outer portion of a side surface of the trench insulation layer, and thus, reliability against water penetration may be enhanced, and an emission layer of the first subpixel may be electrically isolated from an emission layer of the second subpixel, thereby reducing the LLC.

According to embodiments of the invention, a trench insulation layer having a trench structure may be disposed between first and second subpixels, and a portion of a first middle electrode included in the trench insulation layer may have a structure which protrudes to an outer portion of a side surface of the trench insulation layer, and thus, reliability against water penetration may be enhanced, and an emission layer of the first subpixel may be electrically isolated from an emission layer of the second subpixel, thereby reducing the LLC.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display panel, comprising:
a substrate including a first subpixel and a second subpixel in an upper portion thereof;
a trench insulation layer disposed on the substrate and including a trench structure between the first subpixel and the second subpixel;
a first electrode disposed on the trench insulation layer and provided in each of the first and second subpixels;
a bank disposed on the trench insulation layer to cover an edge of the first electrode and expose a portion of the first electrode; and
an emission layer and a second electrode sequentially stacked on the exposed portion of the first electrode, on the bank, and in the trench structure, and provided in each of the first and second subpixels,
wherein the trench insulation layer comprises a first middle electrode therein, and a portion of the first middle electrode protrudes to an outer portion of a side surface of the trench insulation layer configuring the trench structure, and
a first portion of the emission layer extending from the first subpixel and a second portion of the emission layer extending from the second subpixel are isolated from each other by the protruding portion of the first middle electrode, in the trench structure.

2. The display panel of claim 1, wherein a length of the protruding portion of the first middle electrode is greater than a thickness of the emission layer or a thickness of the second electrode, and is less than a thickness of the trench insulation layer.

3. The display panel of claim 1, wherein the trench insulation layer comprises a first planarization layer disposed on the substrate and a second planarization layer disposed on the first planarization layer.

4. The display panel of claim 3, wherein the first middle electrode is disposed between the first planarization layer and the second planarization layer.

5. The display panel of claim 3, wherein each of the first and second subpixels further comprises:
a transistor between the first planarization layer and the substrate; and
a second middle electrode disposed between the first planarization layer and the second planarization layer while being horizontally spaced apart from the first middle electrode, and
wherein the second middle electrode electrically connects the first electrode to one of a source electrode and a drain electrode of the transistor.

6. The display panel of claim 3, wherein a portion of the first middle electrode protrudes to an outer portion of a side surface of each of the first and second planarization layers exposed at an inner portion of the trench structure.

7. The display panel of claim 3, wherein a length by which a portion of the first middle electrode protrudes from an outer portion of a side surface of the first planarization layer is greater than a thickness of the emission layer or a thickness of the second electrode, and is less than a thickness of the first planarization layer or the second planarization layer.

8. The display panel of claim 3, wherein, in the trench structure, the emission layer and the second electrode are stacked on a side surface of the second planarization layer exposed at an inner portion of the trench structure, the protruding portion of the first middle electrode, and a bottom surface of the trench structure.

9. The display panel of claim 1, wherein, in the trench structure, the emission layer and the second electrode stacked on the protruding portion of the first middle electrode are respectively spaced apart from the emission layer and the second electrode stacked under the protruding portion of the first middle electrode.

10. The display panel of claim 1, wherein the bank is spaced apart from an adjacent bank between the first and second subpixels to expose the trench structure.

11. The display panel of claim 1, further comprising an interlayer insulation layer exposed at a bottom surface of the trench structure,
wherein the emission layer and the second electrode are stacked on the interlayer insulation layer exposed at a bottom surface of the trench structure.

12. The display panel of claim 1, further comprising a capping layer or an encapsulation layer disposed on the second electrode and filling the trench structure.

13. The display panel of claim 1, wherein the first and second subpixels are included in one unit pixel and are configured to emit light of different colors.

14. The display panel of claim 1, wherein the trench structure extends in a direction intersecting with a direction in which the first and second subpixels are arranged.

15. The display panel of claim 1, wherein the trench structure comprises first and second trench structures in one unit pixel,
the first trench structure is disposed between two subpixels arranged in a first direction and extends in a second direction intersecting with the first direction,
the second trench structure is disposed between two other subpixels arranged in the first direction and extends in the second direction, and
the first and second trench structures are spaced apart from each other between the two subpixels and the two other subpixels, in one unit pixel.
